(19) United States
(12) Patent Application Publication
(10) Pub. No.: US 2017/0365719 A1
(43) Pub. Date: Dec. 21, 2017

(54) Negative Capacitance Field Effect Transistor

(71) Applicants: Taiwan Semiconductor Manufacturing Co., Ltd., Hsin-Chu (TW); National Taiwan University, Taipei (TW)

(72) Inventors: Miin-Jang Chen, Taipei (TW); Chi-Wen Liu, Hsinchu (TW); Bo-Ting Lin, Taichung City (TW)

(21) Appl. No.: 15/183,352

(22) Filed: Jun. 15, 2016

(51) Int. Cl. H01L 29/78; H01L 29/51; H01L 49/02; H01L 21/02; H01L 29/423; H01L 29/66; H01L 29/49

(52) U.S. Cl. CPC H01L 29/78391; H01L 29/6684; H01L 29/516; H01L 29/513; H01L 29/4966; H01L 21/02189; H01L 29/42364; H01L 28/60; H01L 21/0228; H01L 21/02274; H01L 29/495

(57) ABSTRACT

A gate structure of a negative capacitance field effect transistor (NCFET) is disclosed. The NCFET includes a gate stack disposed over a substrate. The gate stack includes a dielectric material layer, a ferroelectric ZrO₂ layer and a first conductive layer. The NCFET also includes a source/drain feature disposed in the substrate adjacent the gate stack.

### BACKGROUND

The semiconductor integrated circuit (IC) industry has experienced rapid growth. Technological advances in IC design and material have produced generations of ICs where each generation has smaller and more complex circuits than previous generations. In the course of IC evolution, functional density (i.e., the number of interconnected devices per chip area) has generally increased while geometry size (i.e., the smallest component (or line) that can be created using a fabrication process) has decreased.

Transistors are circuit components or elements that are often formed on semiconductor devices. Many transistors may be formed on a semiconductor device in addition to capacitors, inductors, resistors, diodes, conductive lines, or other elements, depending on the circuit design. A field effect transistor (FET) is one type of transistor. Generally, a transistor includes a gate stack formed between source and drain regions. The source and drain regions may include a doped region of a substrate and may exhibit a doping profile suitable for a particular application. The gate stack is positioned over the channel region and may include a gate dielectric interposed between a gate electrode and the channel region in the substrate. Although existing methods of fabricating IC devices have been generally adequate for their intended purposes, they have not been entirely satisfactory in all respects. For an example, improvements in forming a gate stack with a negative capacitance are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4 and 5 are cross-sectional views of an example semiconductor device in accordance with some embodiments.

FIG. 6 is a flowchart of an example method for fabricating a semiconductor device constructed in accordance with some embodiments.

FIGS. 7A, 7B, 8, 9 and 10 are cross-sectional views of an example semiconductor device in accordance with some embodiments.

FIG. 11 is another flowchart of an example method for fabricating a semiconductor device constructed in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments such as those described herein provide a negative capacitance (NC), which can be utilized in forming negative capacitance gate stacks to allow formation of field effect transistor (FET) devices with advantages, such as having lower subthreshold swing (SS). SS represents the easiness of switching the transistor current off and on and is a factor in determining the switching speed of a FET device. SS allows for FET devices having higher switching speed compared to conventional FET devices. NC shows important application in metal-oxide-semiconductor field-effect transistors (MOSFETs) with very short channel length for ultra-low power computing.

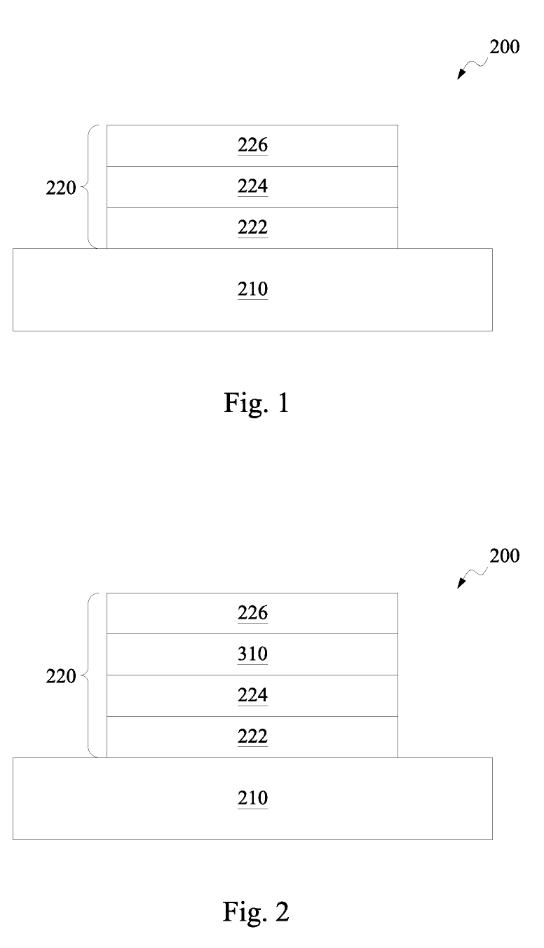

FIG. 1 illustrates a cross-sectional view of a semiconductor structure 200 in accordance with some embodiments. In the illustrated embodiment, the semiconductor structure 200 includes a substrate 210 and a ferroelectric capacitor 220 over the substrate 210. The substrate 210 includes silicon. Alternatively or additionally, the substrate 210 may include other elementary semiconductor such as germanium. The substrate 210 may also include a compound semiconductor such as silicon carbide, gallium arsenic, indium arsenide, and indium phosphide. The substrate 210 may include an alloy semiconductor such as silicon germanium, silicon germanium carbide, gallium arsenic phosphide, and gallium indium phosphide. In one embodiment, the substrate 210 includes an epitaxial layer. For example, the substrate 210 may have an epitaxial layer overlying a bulk semiconductor. Furthermore, the substrate 210 may include a semiconductor-on-insulator (SOI) structure. For example, the substrate 210 may include a buried oxide (BOX) layer formed by a process such as separation by implanted oxygen (SIMOX) or other suitable technique, such as wafer bonding and grinding.

The substrate 210 may also include various p-type doped regions and/or n-type doped regions, implemented by a process such as ion implantation and/or diffusion. Those doped regions include n-well, p-well, light doped region (LDD) and various channel doping profiles configured to form various integrated circuit (IC) devices, such as a complimentary metal-oxide-semiconductor field-effect transistor (CMOSFET), imaging sensor, and/or light emitting diode (LED). The substrate 210 may further include other functional features such as a resistor or a capacitor formed in and on the substrate.

The substrate 210 may also include various isolation regions. The isolation regions separate various device regions in the substrate 210. The isolation regions include different structures formed by using different processing technologies. For example, the isolation region may include shallow trench isolation (STI) regions. The formation of an STI may include etching a trench in the substrate 210 and filling in the trench with insulator materials such as silicon oxide, silicon nitride, and/or silicon oxynitride. The filled trench may have a multi-layer structure such as a thermal oxide liner layer with silicon nitride filling the trench. A chemical mechanical polishing (CMP) may be performed to polish back excessive insulator materials and planarize the top surface of the isolation features.

The ferroelectric capacitor 220 includes a first conductive layer 222 over the substrate 210, a ferroelectric layer 224 over the first conductive layer 222 and a second conductive layer 226 over the ferroelectric layer 224. The ferroelectric capacitor 220 may be formed by one or more procedures such as deposition, patterning and etching processes. In the present embodiment, the first and second conductive layers, 222 and 226, may include a metallic material such as silver, aluminum, copper, tungsten, nickel, platinum, alloys thereof (such as aluminum copper alloy), and/or metal compound (such as titanium nitride or tantalum nitride). The first and second conductive layers, 222 and 226, may also include metal silicide, doped silicon or other suitable conductive material in accordance with some embodiments. The first and second conductive layers, 222 and 226, may include other multiple conductive material films properly designed, such as specifically designed for n-type FET and p-type FET, respectively. The second conductive layer 226 may have the same material as the first conductive layer 222. Alternatively, the second conductive layer 226 may have a different material as the first conductive layer 222. The first and second conductive layers, 222 and 226, may be formed by plating, chemical vapor deposition (CVD), atomic layer deposition (ALD), physical vapor deposition (PVD), combinations thereof, and/or other suitable techniques

The ferroelectric layer 224 includes a ferroelectric zirconium oxide (ZrO₂) layer, which has ferroelectric properties such as a hysteresis loop pattern of electric displacement field vs external electric filed. It is noted that, in the present embodiment, the ferroelectric ZrO₂ layer 224 is a single compound film and exhibits ferroelectricity without additional dopant, which provides advantage of a formation process with less complexity. In an embodiment, the first conductive layer 222 is a platinum (Pt) layer and the ferroelectric ZrO₂ layer 224 is formed over and in physical contact with the Pt layer 222. In another embodiment, the first conductive layer 222 is a titanium nitride (TiN) layer and the ferroelectric ZrO₂ layer 224 is formed over and in physical contact with the TiN layer 222. It is noted also that, in the present embodiment, the ferroelectric ZrO₂ layer 224 can be formed on either a Pt layer 222 or a TiN layer 222, which provides flexibility of an electrode formation.

As a result, the ferroelectric capacitor 220 consists of the first conductive layer 222 as a bottom electrode, the ferroelectric ZrO₂ layer 224 and the second conductive layer 226 as a top electrode. The ferroelectric capacitor 220 has a first capacitance C₁, which is a negative capacitance C_{Zr}O₂.

In the present embodiment, the ferroelectric ZrO₂ layer 224 is formed by plasma enhanced atomic layer deposition (PE-ALD) having a deposition temperature range from about 270° C. to about 500° C. The ferroelectric zirconium oxide (ZrO₂) layer 224 has a thickness range from about 1 nm to about 1 μm.

The present disclosure repeats reference numerals and/or letters in the various embodiments. This repetition is for the purpose of simplicity and clarity such that repeated reference numerals and/or letters indicate similar features amongst the various embodiments unless stated otherwise.

FIG. 2 illustrates a cross-sectional view of a semiconductor structure 200 in accordance with some embodiments. The semiconductor structure 200 in FIG. 2 is similar to the semiconductor structure 200 in FIG. 1. However, in FIG. 2, the ferroelectric capacitor 220 further includes a dielectric layer 310 interposed between the ferroelectric ZrO₂ layer 224 and the second conductive layer 226. The dielectric layer 310 may include silicon oxide, silicon nitride, silicon oxynitride, silicon carbide, high-k dielectric material and/or a combination thereof. The dielectric material layer 310 may be formed by CVD, ALD, spin-on coating and/or other suitable techniques. Thus, a second capacitance C₂ of the ferroelectric capacitor 220 consists of the first conductive layer 222 as a bottom electrode, the ferroelectric ZrO₂ layer 224, the dielectric layer 310 and the second conductive layer 226 as a top electrode.

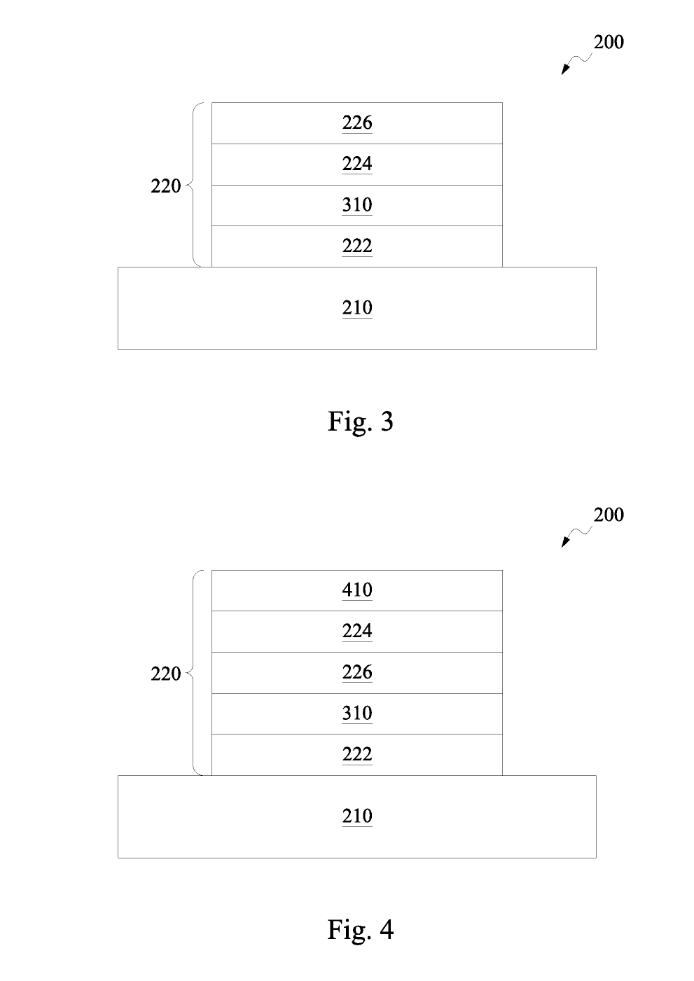

FIG. 3 illustrates a cross-sectional view of a semiconductor structure 200 in accordance with some embodiments. The semiconductor structure 200 in FIG. 3 is similar to the semiconductor structure 200 in FIG. 2. For example, the ferroelectric capacitor 220 includes the dielectric layer 310. However, in FIG. 3, the dielectric layer 310 is interposed between the first conductive layer 222 and the ferroelectric ZrO₂ layer 224. Thus, a third capacitance C₃ of the ferroelectric capacitor 220 consists of the first conductive layer 222 as a bottom electrode, the dielectric layer 310, the ferroelectric ZrO₂ layer 224 and the second conductive layer 226 as a top electrode.

FIG. 4 illustrates a cross-sectional view of a semiconductor structure 200 in accordance with some embodiments. The semiconductor structure 200 in FIG. 4 is similar to the semiconductor structure 200 in FIG. 3. For example, the ferroelectric capacitor 220 includes the dielectric layer 310. However, in FIG. 4, the dielectric layer 310 is formed over the first conductive layer 222, the second conductive layer 226 is formed over the dielectric layer 310 and the ferroelectric ZrO₂ layer 224 is formed over the second conductive layer 226. In an embodiment, the second conductive layer 226 is a Pt layer and the ferroelectric ZrO₂ layer 224 is formed over and in physical contact with the Pt layer 226. In another embodiment, the second conductive layer 226 is a TiN layer and the ferroelectric ZrO₂ layer 224 is formed over and in physical contact with the TiN layer 226.

However, in the present embodiment, the ferroelectric capacitor 220 further includes a third conductive layer 410 disposed over the ferroelectric ZrO₂ layer 224. The third conductive layer 410 may be similar to the first and second conductive layers, 222 and 226, in terms of composition and formation. Thus, a fourth capacitance C₄ of the ferroelectric capacitor 220 consists of the first conductive layer 222 as a bottom electrode, the dielectric layer 310, the second conductive layer 226 as an internal electrode, the ferroelectric ZrO₂ layer 224 and the third conductive layer 410 as a top electrode.

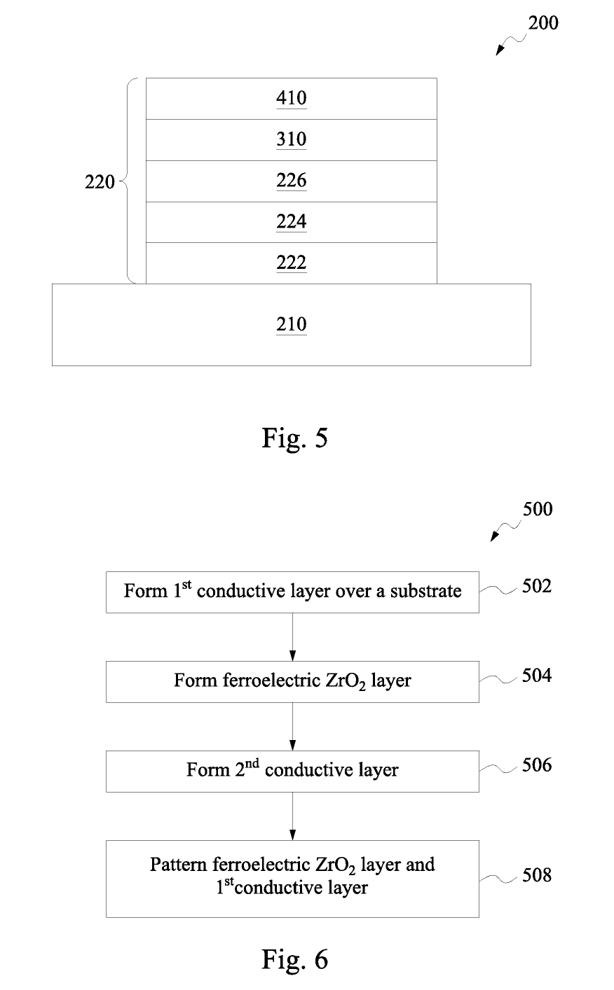

FIG. 5 illustrates a cross-sectional view of a semiconductor structure 200 in accordance with some embodiments. The semiconductor structure 200 in FIG. 5 is similar to the semiconductor structure 200 in FIG. 4. For example, the ferroelectric capacitor 220 includes the dielectric layer 310 and the third conductive layer 410. However, comparing to FIG. 4, in FIG. 5, the dielectric layer 310 switches its position with the ferroelectric ZrO₂ layer 224. In other words, the ferroelectric ZrO₂ layer 224 is formed over the first conductive layer 222, the second conductive layer 226 is formed over the ferroelectric ZrO₂ layer 224, the dielectric layer 310 is formed over the second conductive layer 226 and the third conductive layer 410 is formed over the dielectric layer 310. In an embodiment, the first conductive layer 222 is Pt layer and the ferroelectric ZrO₂ layer 224 is formed over and in physical contact with the Pt layer 222. In another embodiment, the first conductive layer 222 is a TiN layer and the ferroelectric ZrO₂ layer 224 is formed over and in physical contact with the TiN layer 222. Thus, a fifth capacitance C5 of the ferroelectric capacitor 220 consists of the first conductive layer 222 as a bottom electrode, the ferroelectric ZrO₂ layer 224, the second conductive layer 226 as an internal electrode, the dielectric layer 310 and the third conductive layer 410 as a top electrode.

As a result, a total capacitance Cₜₒₜₐₗ of the ferroelectric capacitor 220, (namely C₂, C₃, C₄ and C₅, in FIG. 2, FIG. 3, FIG. 4 and FIG. 5, respectively), is contributed by the negative capacitance C_{ZrO2} in series with a dielectric capacitance C_{dielectric}, contributed by the dielectric layer 310, such that (1/Cₜₒₜₐₗ)=(1/C_{ZrO2})+(1/C_{dielctric}). When the absolute value of C_{ZrO2} is larger than C_{dielctric}, the total capacitance Cₜₒₜₐₗ will be larger than C_{dielctric}, which has profound impact on the design of negative capacitance FET (NCFET).

The semiconductor structure 200 may undergo further CMOS or MOS technology processing to form various features and regions known in the art. For example, subsequent processing may form a multilayer interconnection includes vertical interconnects, such as conventional vias or contacts, and horizontal interconnects, such as metal lines. The various interconnection features may implement various conductive materials including copper, tungsten, and/or silicide to provide electrical routings to couple various devices in the substrate 210 to the input/output power and signals.

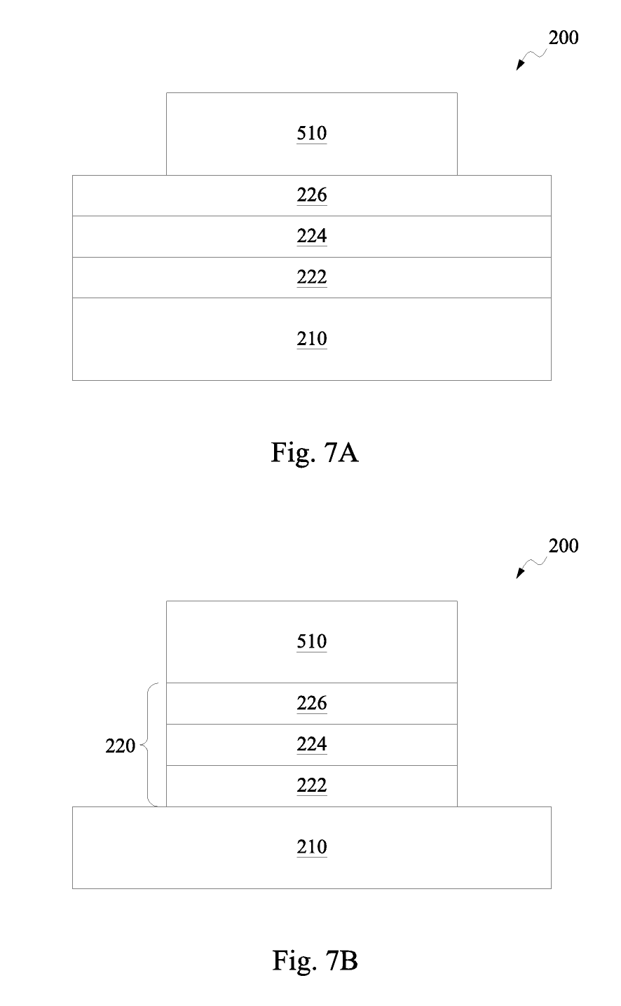

FIG. 6 illustrates a flowchart of a method 500 making the semiconductor structure 200, constructed according to some embodiments. Referring to FIGS. 6 and 7A, the method 500 includes an operation 502 to form the first conductive layer 222 over the substrate 210. The first conductive layer 222 may be formed by plating, CVD, ALD, PVD, combinations thereof, and/or other suitable techniques.

Referring also to FIGS. 6 and 7A, the method 500 also includes an operation 504 to form the ferroelectric ZrO₂ layer 224 over the first conductive layer 222. The ferroelectric ZrO₂ layer 224 is formed by PE-ALD with a process temperature range from about 270° C. to about 500° C. In the present embodiment, a ferroelectric property is achieved for the ferroelectric ZrO₂ layer 224 by PE-ALD using tetrakis-(dimethylamino) zirconium (TDMAZ, Zr [N(CH₃)₂]₄) and oxygen as the precursors and at about 300° C. deposition temperature. It is noted that, in the present embodiment, the ferroelectric ZrO₂ layer 224 is formed to achieve ferroelectricity without a doping and an annealing process, which not only reduces process complexity but also relaxing temperature constrains in process integration.

In an embodiment, the ferroelectric ZrO₂ layer 224 is formed over and in physical contact with the Pt layer 222. In another embodiment, the first conductive layer 222 is a TiN layer and the ferroelectric ZrO₂ layer 224 is formed over and in physical contact with the TiN layer 222. Additionally, an annealing process may be further applied to the ferroelectric ZrO₂ layer 224.

Referring also to FIGS. 6 and 7A, the method 500 also includes an operation 506 to form the second conductive layer 226 over the ferroelectric ZrO₂ layer 224. The second conductive layer 226 may be formed by plating, CVD, ALD, PVD, combinations thereof, and/or other suitable techniques.

Referring to FIGS. 6, 7A and 7B, the method 500 also includes an operation 508 to pattern the second conductive layer 226, the ferroelectric ZrO₂ layer 224 and the first conductive layer 222 to form the ferroelectric capacitor 220. The ferroelectric ZrO₂ layer 224 and the first conductive layer 222 may be patterned individually, and/or together. In an embodiment, a patterned photoresist layer 510 is formed over the second conductive layer 226 and an etch process is performed to etch the second conductive layer 226, the ferroelectric ZrO₂ layer and the first conductive layer 222 through the patterned photoresist layer 510, as shown in FIG. 7B.

Additional steps can be provided before, during, and after the method 500, and some of the steps described can be replaced or eliminated for other embodiments of the method. For example, before form the second conductive layer 226, the dielectric layer 310 is formed over the ferroelectric ZrO₂ layer 224 by CVD, PVD, ALD, and/or other suitable processes. Then the dielectric layer 310 is patterned together with the second conductive layer 226, the ferroelectric ZrO₂ layer 224 and the first conductive layer 222.

Embodiments such as those described herein provide a NCFET with negative capacitance gate stack to allow formation of FET devices with advantages such as a lower SS. The NC gate stack has a gate dielectric layer, a conductive layer and a ferroelectric layer stacked together. In various embodiments, the semiconductor device has a single gate stack, double gate stacks, or multiple gate stacks, such as fin-like FET (FinFET). A FET is provided in accordance with various exemplary embodiments. The intermediate stages of forming the FET are illustrated. The variations of the embodiments are discussed. Throughout the various views and illustrative embodiments, like reference numbers are used to designate like elements.

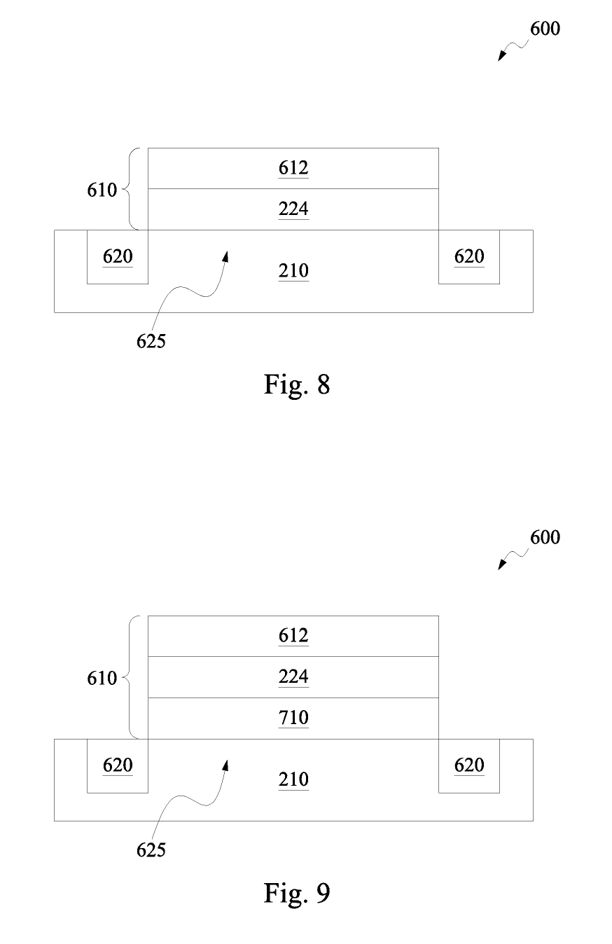

FIG. 8 illustrates a cross-sectional view of a semiconductor structure 600 in accordance with some embodiments. In the illustrated embodiment, the semiconductor structure 600 includes the substrate 210, a gate stack 610 on the substrate 210, source and drain features 620 disposed on two sides of the gate stack 610, and a channel region 625 disposed between the source and drain features 620. The gate stack 610 may be formed by one or more procedures such as deposition, patterning and etching processes. In the present embodiment, the gate stack 610 includes the ferroelectric ZrO₂ layer 224 disposed over the substrate 210 and a gate electrode layer 612 disposed over the ferroelectric ZrO₂ layer 224. The electrode layer may include a single layer or alternatively a multi-layer structure, such as various combinations of a metal layer with a work function to enhance the device performance (work function metal layer), liner layer, wetting layer, adhesion layer and a conductive layer of metal, metal alloy or metal silicide). The electrode layer may include Ti, Ag, Al, TiAlN, TaC, TaCN, TaSiN, Mn, Zr, TiN, TaN, Ru, Mo, Al, WN, Cu, W, any suitable materials and/or a combination thereof. The gate electrode layer 612 may be formed by CVD, PVD, and/or other suitable processes.

The S/D features 620 may include germanium (Ge), silicon (Si), gallium arsenide (GaAs), aluminum gallium arsenide (AlGaAs), silicon germanium (SiGe), gallium arsenide phosphide (GaAsP), gallium antimony (GaSb), indium antimony (InSb), indium gallium arsenide (InGaAs), indium arsenide (InAs), or other suitable materials. The S/D features 620 may be formed by epitaxial growing processes, such as CVD deposition techniques (e.g., vapor-phase epitaxy (VPE) and/or ultra-high vacuum CVD (UHV-CVD)), molecular beam epitaxy, and/or other suitable processes.

As discussed above, the gate stack 610 includes the ferroelectric ZrO₂ layer 224 and the gate electrode layer 612. A first gate capacitance C_{G1} is contributed by the NC C_{ZrO2}, which is in series with a substrate capacitance Cs contributed by the substrate 210.

FIG. 9 illustrates a schematic cross-sectional view of a semiconductor structure 600 in accordance with some embodiments. The semiconductor structure 600 in FIG. 9 is similar to the semiconductor structure 600 in FIG. 8. However, in FIG. 9, the gate stack 610 further includes a gate dielectric layer 710 interposed between the ferroelectric ZrO₂ layer 224 and the substrate 210.

The gate dielectric layer 710 may include an interfacial layer (IL) and a high-k (HK) dielectric layer deposited by suitable techniques, such as CVD, ALD, PVD, thermal oxidation, combinations thereof, and/or other suitable techniques. The IL may include oxide, HfSiO and oxynitride and the HK dielectric layer may include LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, silicon oxynitrides (SiON), and/or other suitable materials.

As discussed above, the gate stack 610 includes the gate dielectric layer 710, the ferroelectric ZrO₂ layer 224 and the gate electrode layer 612. A second gate capacitance C_{G2} is contributed by the NC C_{ZrO2} and is in series with a dielectric capacitance C_{dielectric}, such that (1/C_{G2})=(1/C_{ZrO2})+(1/C_{dielectric}).

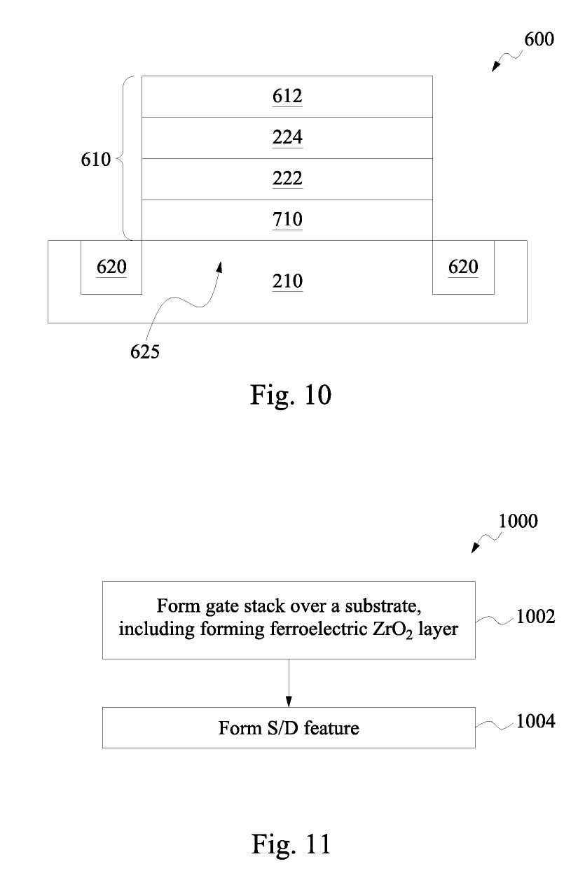

FIG. 10 illustrates a cross-sectional view of a semiconductor structure 600 in accordance with some embodiments. The semiconductor structure 600 in FIG. 10 is similar to the semiconductor structure 600 in FIG. 9. For example, the gate stack 610 includes the gate dielectric layer 710. However, in FIG. 10, the gate stack 610 further includes the first conductive layer 222 interposed between the ferroelectric ZrO₂ layer 224 and the gate dielectric layer 710. In an embodiment, the first conductive layer 222 is Pt layer and the ferroelectric ZrO₂ layer 224 is formed over and in physical contact with the Pt layer 222. In another embodiment, the first conductive layer 222 is a TiN layer and the ferroelectric ZrO₂ layer 224 is formed over and in physical contact with the TiN layer 222. In some embodiments, the first conductive layer 222 serves as internal gate or a floating gate to average out a non-uniform charge in the ferroelectric ZrO₂ layer 224 and non-uniform potential profile along S/D direction.

As discussed above, the gate stack 610 includes the gate dielectric layer 710, the floating gate 222, the ferroelectric ZrO₂ layer 224 and the gate electrode layer 612. A third gate capacitance C_{G3} is contributed by the NC C_{ZrO2} and is in series with a dielectric capacitance C_{dielctric}, such that (1/C_{G3})=(1/C_{ZrO2})+(1/C_{dielectric}).

As a result, a gate capacitance C_{G} of the gate stack 610, (namely C_{G2} in FIG. 9 and C_{G3} in FIG. 10), is contributed by the negative capacitance C_{ZrO2} in series with a dielectric capacitance C_{dielctric}, such that (1/C_{G total})=(1/C_{ZrO2})+(1/C_{dielectric}). When the absolute value of C_{ZrO2} is larger than C_{dielctric}, the gate capacitance C_{G} will be larger than C_{dielctric}, which enhances gate control. The gate capacitance C_{G} is in series with a substrate capacitance Cs contributed by the substrate 210. A subthreshold swings (SS) is usually given as:

$$SS = ( 1 + \frac{{C}_{S}}{{C}_{G}} ) 60 \frac{mV}{decade}$$

where a decade corresponds to a 10 times increase of a drain current. When the absolute value of C_{ZrO2} is smaller than C_{dielctric}, the C_{G} will be negative and SS will be less than 60 mV.

The semiconductor structure 600 may undergo further CMOS or MOS technology processing to form various features and regions known in the art. For example, subsequent processing may form a multilayer interconnection includes vertical interconnects, such as conventional vias or contacts, and horizontal interconnects, such as metal lines. The various interconnection features may implement various conductive materials including copper, tungsten, and/or silicide to provide electrical routings to couple various devices in the substrate 210 to the input/output power and signals.

FIG. 11 illustrates a flowchart of a method 1000 making the semiconductor structure 600, constructed according to some embodiments. The method 1000 includes an operation 1002 to form the gate stack 610 over the substrate 210. In the operation 1002, the formation of the gate stack 610 includes depositing various gate material layers, such as the ferroelectric layer 224, the gate dielectric material layer 710, the first conductive layer 222 and the gate electrode layer 612. The ferroelectric ZrO₂ layer 224 is deposited by PE-ALD with a process temperature range from about 270° C. to about 500° C. In the present embodiment, a ferroelectric property is achieved for the ferroelectric ZrO₂ layer 224 by PE-ALD using tetrakis-(dimethylamino) zirconium (TDMAZ, Zr[N(CH₃)₂]₄) and oxygen as the precursors and at about 300° C. deposition temperature. Additionally, an annealing process may be further applied to the ferroelectric ZrO₂ layer 224.

The gate dielectric material layer 710 is deposited by CVD, PVD, ALD, and/or other suitable processes. The first conductive layer 222 and the gate electrode layer 612 are deposited by plating, CVD, PVD, ALD, and/or other suitable processes. After the depositions the gate material layers are patterned to form gate stack 610. The patterning further includes lithography process and etching. A hard mask layer may be used to pattern the gate stack 610. Film layers of the gate stack 610, such as the ferroelectric ZrO₂ layer 224, the gate dielectric layer 710, the first conductive layer 222 and the gate electrode layer 612 may be patterned individually, and/or together.

The method 1000 also includes an operation 1004 to form S/D features 620, such that S/D features 620 are aligned on the edges of the gate stack 610. In the operation 1004, the S/D features 620 may be formed by one or more ion implantation. In some embodiments, for straining effect or other performance enhancement, the S/D features 620 may be formed by epitaxy growth of different semiconductor materials. For example, the substrate 210 within the S/D region is recessed by etching, and a semiconductor material is epitaxially grown on the recessed region with in-situ doping to form the S/D features 620.

In alternative embodiments, the method 1000 may form the gate stack 610 after the formation of the S/D features 620, such as in a gate-last procedure. For examples, a dummy gate is formed; the S/D features 620 are formed on sides of the dummy gate by the operation 2004; and thereafter, the gate stack 610 is formed to replace the dummy gate by a gate replacement process.

One example of the gate-replacement process is described below. One or more dielectric material (such as silicon oxide, low-k dielectric material, other suitable dielectric material, or a combination thereof) is formed on the dummy gate and the substrate 210. A polishing process, such as chemical mechanical polishing (CMP), is applied to planarize the top surface, thereby forming an interlayer dielectric layer (ILD). The dummy gate is removed by etching, resulting in a gate trench in the ILD. Then the gate stack 610 is formed in the gate trench by depositions and charging treatment, which are similar to those in the operation 1002. However, the patterning in the operation 1002 may be skipped. However, another CMP process may be followed to remove excessive the gate materials and planarize the top surface.

Additional steps can be provided before, during, and after the method 1000, and some of the steps described can be replaced or eliminated for other embodiments of the method. For example, the method 1000 may also include other operations to form various features and components, such as other features for a negative capacitance FET. For examples, an interconnect structure is formed on the substrate 210 and configured to couple various devices into a functional circuit. The interconnection structure includes metal lines distributed in multiple metal layers; contacts to connect the metal lines to devices (such as sources, drains and gates); and vias to vertically connect metal lines in the adjacent metal layers. The formation of the interconnect structure includes damascene process or other suitable procedure. The metal components (metal lines, contacts and vias) may include copper, aluminum, tungsten, metal alloy, silicide, doped polysilicon, other suitable conductive materials, or a combination thereof.

Based on the above, the present disclosure offers a semiconductor gate structure with negative capacitance of a ferroelectric capacitor. The ferroelectric capacitor employs a ferroelectric ZrO₂ layer, which is able to be formed over either Pt layer or TiN layer. The present disclosure also offers a method of forming a ferroelectric ZrO₂ layer without annealing and doping processes. The method demonstrates a less-complexity, flexible and low cost method for forming a ferroelectric layer.

The present disclosure provides many different embodiments of a semiconductor device that provide one or more improvements over existing approaches. In one embodiment, a semiconductor device includes a substrate and a ferroelectric capacitor disposed over the substrate. The ferroelectric capacitor includes a ferroelectric ZrO₂ layer and a first conductive layer.

In another embodiment, a device includes a gate stack disposed over a substrate. The gate stack includes a dielectric material layer, a ferroelectric ZrO₂ layer and a first conductive layer. The device also includes a source/drain feature disposed in the substrate adjacent the gate stack.

In yet another embodiment, a method forming a semiconductor device includes forming a ferroelectric ZrO₂ layer over a semiconductor substrate, forming a conductive layer over the semiconductor substrate, forming a dielectric material layer over the semiconductor substrate and patterning the ferroelectric ZrO₂ layer, the conductive layer, and the first dielectric material layer to form a gate stack. The method also includes forming a source/drain feature in the substrate adjacent the gate stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device comprising:
a substrate; and
a ferroelectric capacitor disposed over the substrate, wherein the ferroelectric capacitor includes:
a first conductive layer disposed over the substrate;
a ferroelectric ZrO₂ layer disposed over the first conductive layer, wherein the ferroelectric ZrO₂ layer consists essentially of ZrO₂; and
a second conductive layer disposed over the ferroelectric ZrO₂ layer.

2. The semiconductor device of claim 1, wherein the ferroelectric ZrO₂ layer is disposed on the first conductive layer.

3. The semiconductor device of claim 2, wherein the first conductive layer includes at least one material selected from the group consisting of silver, aluminum, copper, tungsten, nickel, platinum, alloys thereof and a metal compound.

4. The semiconductor device of claim 2, wherein the first conductive layer includes a titanium nitride layer.

5. (canceled)

6. The semiconductor device of claim 1, further comprising a dielectric layer interposed between the ferroelectric ZrO₂ layer and the second conductive layer.

7. The semiconductor device of claim 1, further comprising a dielectric layer interposed between the first conductive layer and the ferroelectric ZrO₂ layer.

8. The semiconductor device of claim 1, further comprising:
a dielectric layer disposed over the second conductive layer; and
a third conductive layer disposed over the dielectric layer.

9. The semiconductor device of claim 1, further comprising:
a dielectric layer interposed between the substrate and the first conductive layer; and
a fourth conductive layer interposed between the substrate and the dielectric layer.

10-20. (canceled)

21. A capacitor comprising:
a semiconductor substrate;
a first conductive layer disposed over a semiconductor substrate;
a ferroelectric ZrO₂ layer disposed over the first conductive layer;
a dielectric layer disposed over the first conductive layer; and
a second conductive layer disposed over the dielectric layer,
wherein the capacitor has a first positive capacitance,
wherein the ferroelectric ZrO₂ layer contributes to a negative capacitance,
wherein the ferroelectric ZrO₂ layer consists essentially of ZrO₂ and
wherein the dielectric layer contributes to a second positive capacitance.

22. The capacitor of claim 21, wherein the first conductive layer and the second conductive layer are formed of the same material.

23. The capacitor of claim 21, wherein the first conductive layer and the second conductive layer are formed of different materials.

24. The capacitor of claim 21, wherein the ferroelectric ZrO₂ layer extends from the first conductive layer to the dielectric layer.

25. The capacitor of claim 21, wherein the ferroelectric ZrO₂ layer extends from the dielectric layer to the second conductive layer.

26. The capacitor of claim 21, further comprising a third conductive layer, and
wherein the ferroelectric ZrO₂ layer extends from the second conductive layer to the third conductive layer.

27. A device comprising:
a semiconductor substrate; and
a capacitor disposed over the semiconductor substrate, wherein the capacitor includes:
a dielectric layer disposed over the semiconductor substrate;
a first conductive layer disposed over the semiconductor substrate;
a second conductive layer disposed over the semiconductor substrate; and
a ferroelectric ZrO₂ layer disposed over the semiconductor substrate,
wherein the capacitor has a first positive capacitance,
wherein the ferroelectric ZrO₂ layer consists essentially of ZrO₂ and contributes to a negative capacitance, and
wherein the dielectric layer contributes to a second positive capacitance.

28. The device of claim 27, wherein the ferroelectric ZrO₂ layer physically contacts the first conductive layer, and wherein the first conductive layer includes platinum.

29-30. (canceled)

31. The semiconductor device of claim 1, wherein the ferroelectric ZrO₂ layer is dopant free.

32. The semiconductor device of claim 1, wherein the ferroelectric capacitor has a negative capacitance.

33. The capacitor of claim 21, wherein an absolute value of the negative capacitance is larger than the second positive capacitance, and wherein the first positive capacitance is larger than the second positive capacitance.

34. The device of claim 27, wherein an absolute value of the negative capacitance is larger than the second positive capacitance, and wherein first positive capacitance is larger than the second positive capacitance.
